(19) United States
(12) Patent Application Publication
(10) Pub. No.: US 2025/0155790 A1
(43) Pub. Date: May 15, 2025

(54) PHOTOMASK FOR EXTREME ULTRAVIOLET LITHOGRAPHY AND REPAIR METHOD THEREOF

(71) Applicant: SAMSUNG ELECTRONICS CO., LTD., SUWON-SI (KR)

(72) Inventors: Jimin LIM, Suwon-si (KR); Sang-Hyeon LEE, Suwon-si (KR); Hoil KI, Suwon-si (KR)

(21) Appl. No.: 18/663,227

(22) Filed: May 14, 2024

(30) Foreign Application Priority Data
Nov. 9, 2023 (KR) 10-2023-0154464

(51) Int. Cl. G03F 1/24; G03F 1/48; G03F 1/54; G03F 1/74

(52) U.S. Cl. CPC G03F 1/24; G03F 1/48; G03F 1/54; G03F 1/74

(57) ABSTRACT

A photomask includes a mask substrate. A reflective layer is disposed on a first surface of the mask substrate. A capping layer is disposed on the reflective layer. An absorber layer pattern is disposed on the capping layer. The absorber layer pattern defines an opening that light sources of extreme ultraviolet wavelengths pass through. A side wall of the absorber layer pattern exposed by the opening includes an inclined surface on an upper portion disposed away from the capping layer and a curved surface on a lower portion adjacent to the capping layer.

### CROSS-REFERENCE TO RELATED APPLICATION

This application claims priority under 35 U.S.C. § 119 to Korean Patent Application No. 10-2023-0154464, filed on Nov. 9, 2023 in the Korean Intellectual Property Office, the disclosure of which is incorporated by reference in its entirety herein.

### 1. TECHNICAL FIELD

The present disclosure relates to a photomask for an extreme ultraviolet lithography and a method of repairing the same.

### 2. DISCUSSION OF RELATED ART

As design rules of semiconductor devices decrease, a wavelength of light used in a lithography process is also decreasing. For example, KrF with a wavelength of 248 nm or Arf with a wavelength of 193 nm may be used as a light source. In addition, a lithography process using extreme ultraviolet (EUV) with a wavelength of 13.4 nm, which is less than the wavelengths of Krf and Arf, is being developed as a light source.

The EUV lithography process uses a reflective optical system instead of a transmission optical system using Krf or Arf as a light source. A mask used in the EUV lithography process has a different structure from a mask used in an existing optical process using Krf or Arf. The mask used in the EUV lithography process may have a structure that includes a reflective layer of a multi-layered structure with high reflectance and an absorber layer that absorbs the EUV light source and is patterned.

### SUMMARY

Embodiments of the present disclosure involve repairing microscopic defects in photomasks for an extreme ultraviolet lithography.

According to an embodiment of the present disclosure, a photomask includes a mask substrate. A reflective layer is disposed on a first surface of the mask substrate. A capping layer is disposed on the reflective layer. An absorber layer pattern is disposed on the capping layer. The absorber layer pattern defines an opening that light sources of extreme ultraviolet wavelengths pass through. A side wall of the absorber layer pattern exposed by the opening includes an inclined surface on an upper portion disposed away from the capping layer and a curved surface on a lower portion adjacent to the capping layer.

According to an embodiment of the present disclosure, a photomask includes a mask substrate. A reflective layer is disposed on a first surface of the mask substrate. A capping layer is disposed on the reflective layer. An absorber layer pattern is disposed on the capping layer. The absorber layer pattern defines an opening that light sources of extreme ultraviolet wavelengths pass through. A side wall of an uppermost layer of the absorber layer pattern includes an inclined surface. A side wall of the absorber layer pattern extending from the inclined surface to an upper surface of the capping layer includes a curved surface.

According to an embodiment of the present disclosure, a repair method of a photomask includes providing a photomask including a mask substrate, a reflective layer disposed on a first surface of the mask substrate, a capping layer disposed on the reflective layer, and an absorber layer pattern disposed on the capping layer. The absorber layer pattern defines an opening that light sources of extreme ultraviolet wavelengths pass through. A precursor is supplied to the photomask. An electron beam is irradiated to a portion of the absorber layer pattern that includes at least a portion of a defective region of the photomask and to a portion of the capping layer adjacent to the portion of the absorber layer pattern.

According to embodiments of the present disclosure, microscopic defects in a photomask for extreme ultraviolet lithography may be repaired.

### BRIEF DESCRIPTION OF THE DRAWINGS

FIG. 1 is a schematic perspective view showing a state before a repair of a photomask for an extreme ultraviolet lithography according to an embodiment of the present disclosure.

FIG. 2 is a schematic perspective view showing a state after a repair of a photomask for an extreme ultraviolet lithography according to an embodiment of the present disclosure.

FIG. 3 is a cross-sectional view cut along I-I′ in FIG. 2 according to an embodiment of the present disclosure.

FIG. 4 is an enlarged cross-sectional view showing a region P1 in FIG. 3 according to an embodiment of the present disclosure.

FIG. 5 is an enlarged cross-sectional view showing a region P2 in FIG. 3 according to an embodiment of the present disclosure.

FIG. 6 to FIG. 14 are cross-sectional views to explain a repair method of a photomask for an extreme ultraviolet lithography according to embodiments of the present disclosure.

### DETAILED DESCRIPTION OF EMBODIMENTS

The present invention will be described more fully hereinafter with reference to the accompanying drawings, in which non-limiting embodiments of the present disclosure are shown. As those skilled in the art would realize, the described embodiments may be modified in various different ways, all without departing from the spirit or scope of the present disclosure.

To clarify the present invention, parts that are not connected with the description may be omitted, and the same elements or equivalents are referred to by the same reference numerals throughout the specification.

Further, since sizes and thicknesses of constituent members shown in the accompanying drawings may be arbitrarily given for better understanding and ease of description, embodiments of the present disclosure are not necessarily limited to the illustrated sizes and thicknesses. In the drawings, the thickness of layers, films, panels, regions, etc., may be exaggerated for clarity. In the drawings, for better understanding and ease of description, thicknesses of some layers and areas may be excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

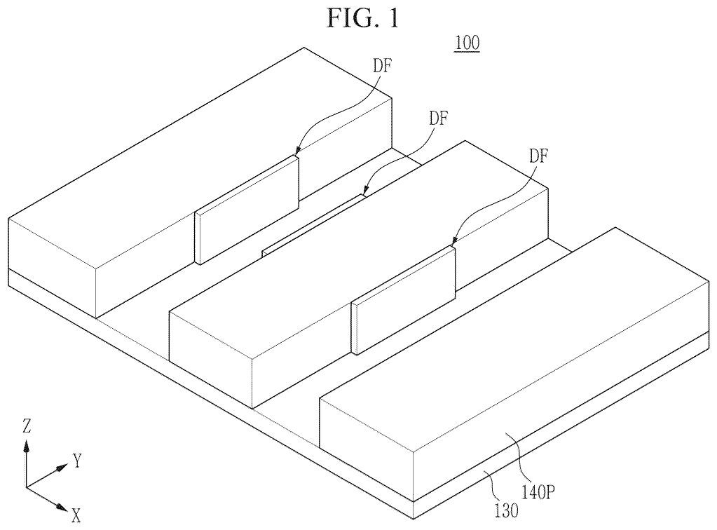

Hereinafter, a photomask for an extreme ultraviolet lithography and a repair method thereof according to embodiments of the present disclosure are described with reference to FIG. 1 to FIG. 14.

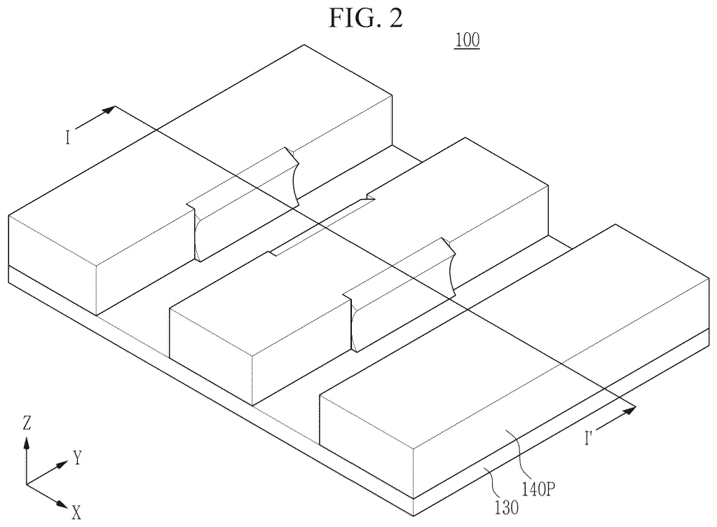

FIG. 1 is a schematic perspective view showing a state before a repair of a photomask for an extreme ultraviolet lithography according to an embodiment. FIG. 2 is a schematic perspective view showing a state after a repair of a photomask for an extreme ultraviolet lithography according to an embodiment. Hereinafter, a photomask for an extreme ultraviolet lithography may be referred to as a photomask for convenience.

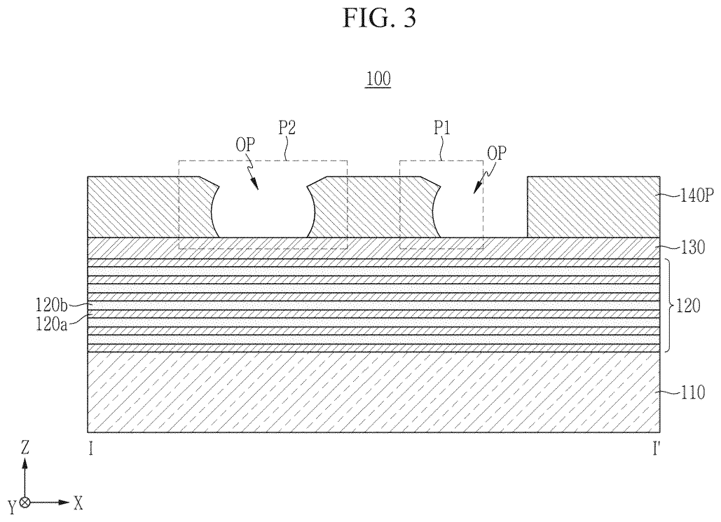

A photomask 100 according to an embodiment may include a mask substrate (110 of FIG. 3), a reflective layer (120 of FIG. 3) disposed on (e.g., disposed directly thereon) one surface of the mask substrate, a capping layer 130 disposed on (e.g., disposed directly thereon) the reflective layer, and an absorber layer pattern 140P disposed on (e.g., disposed directly thereon) the capping layer 130. In an embodiment, the mask substrate, the reflective layer, the capping layer 130, and the absorber layer pattern 140P may be sequentially disposed along a Z direction. In FIG. 1 and FIG. 2, for convenience, the mask substrate (110 in FIG. 3) and the reflective layer (120 in FIG. 3) are omitted.

In an embodiment, the photomask 100 of FIG. 1 may be in a state in which the absorber layer pattern 140P is formed by patterning the absorber layer, and the photoresist pattern disposed on the absorber layer pattern 140P is removed. Referring to FIG. 1, the photomask 100 may include one or more defect regions DF. In an embodiment, the defect region DF should be etched in the process of patterning the absorber layer of the photomask 100, but may refer to a region that remains without being etched. In FIG. 1, the defect region DF may be a region protruding in the X direction from the side wall of the absorber layer pattern 140P.

The defect region DF may be formed on one or both sides of both opposing sidewalls of the absorber layer pattern 140P. In FIG. 1, for convenience, the first type defect region DF formed on one side of both facing sidewalls of the absorber layer pattern 140P and the second type defect region DF formed on both sides of both facing sidewalls of the absorber layer pattern 140P are shown as being positioned adjacent to each other. However, embodiments of the present disclosure are not necessarily limited thereto and the first type defect region DF and the second type defect region DF may be formed to be spaced apart from each other. Additionally, in some embodiments the first type defect region DF and the second type defect region DF may not exist simultaneously on one mask substrate.

The photomask 100 of FIG. 2 may be a state that the process of repairing the defect region DF has been performed at the photomask 100 of FIG. 1. In an embodiment, the repair process may be performed using an etching device using an electron beam. For example, in an embodiment, while supplying a precursor to the photomask 100, an electron beam may be irradiated to the defect region DF to activate the reaction between the material of the absorber layer pattern 140P and the supplied precursor. The material of the absorber layer pattern 140P may be removed by reacting with the precursor.

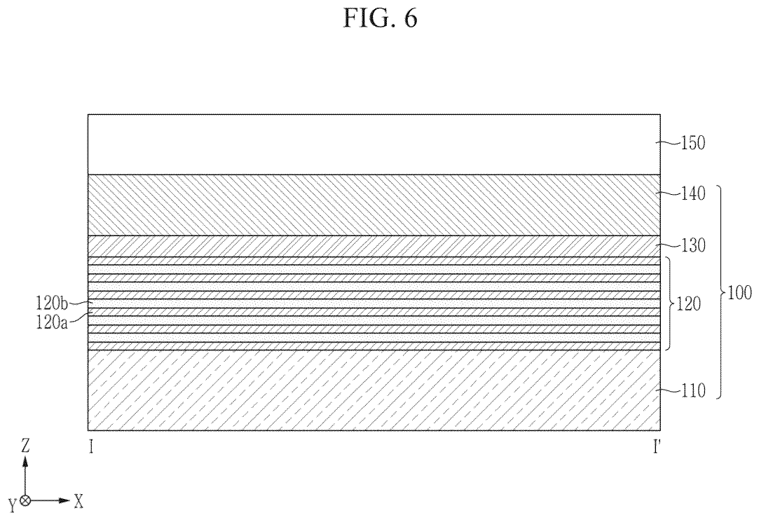

According to an embodiment, the width (e.g., a width in the X direction in FIG. 1) of the defect region DF may be less than about 15 nm. In general, repair devices using electron beams may only repair defects with a width greater than or equal to about 15 nm due to the resolution limit of the electron beam. Accordingly, it may be difficult to repair the defect region DF with a width of less than about 15 nm by using existing repair methods. According to embodiments of the present disclosure, a method for repairing microscopic defects of less than about 15 nm and a repaired photomask is provided. The detailed explanation of the photomask repair method will be described later with reference to FIG. 6 to FIG. 14.

Hereinafter, the photomask 100 after performing the repair process for the defect region DF of FIG. 1 is described with reference to FIG. 3 to FIG. 5.

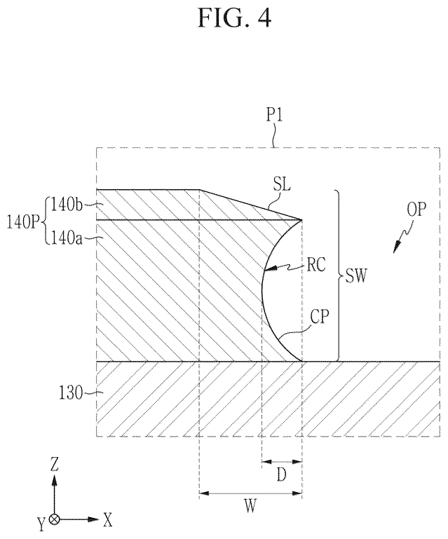

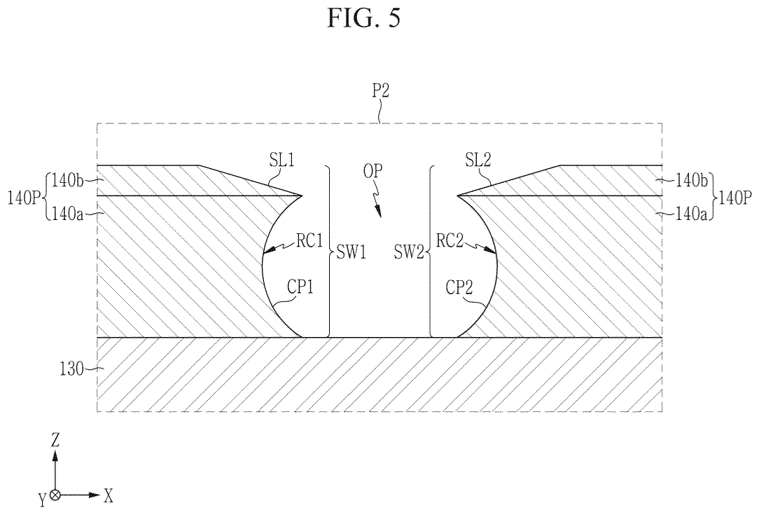

FIG. 3 is a cross-sectional view cut along I-I′ in FIG. 2. FIG. 4 is an enlarged cross-sectional view showing a region P1 in FIG. 3. FIG. 5 is an enlarged cross-sectional view showing a region P2 in FIG. 3.

Referring to FIG. 3, the photomask 100 according to an embodiment may include a mask substrate 110, a reflective layer 120 disposed on (e.g., disposed directly thereon) one surface (e.g., an upper surface in the Z direction) of the mask substrate 110, a capping layer 130 disposed on (e.g., disposed directly thereon) the reflective layer 120, and an absorber layer pattern 140P that is disposed on (e.g., disposed directly thereon) the capping layer 130 and defines an opening OP that allows light sources of the extreme ultraviolet wavelengths to pass through.

In an embodiment, the mask substrate 110 may be made of dielectric material, glass, semiconductor, or metallic material. In some embodiments, the mask substrate 110 may be made of a material with a low thermal expansion coefficient. For example, in an embodiment the mask substrate 110 may have a thermal expansion coefficient of 0±0.05×10-7/° C. at 20° C.

In addition, the mask substrate 110 may be made of a material with high smoothness, planarity, and resistance to cleaning solutions. For example, in an embodiment the mask substrate 110 is synthesis quartz glass, quartz glass, alumino silicate glass, soda lime glass, LTEM (low thermal expansion material) glass such as SiO₂—TiO₂ series glass, crystallization glass precipitated from β quartz solid solution, and monocrystalline glass, or silicon, or SiC.

In an embodiment, the mask substrate 110 may include one surface (e.g., an upper surface in the Z direction) that extends in a plane in an X direction and a Y direction that intersects the X direction. For example, in an embodiment, the X, Y and Z directions may be perpendicular to each other. However, embodiments of the present disclosure are not necessarily limited thereto and the X, Y and Z directions may cross each other at various different angles. The one surface may be referred to as a “first surface”. The reflective layer 120, the capping layer 130, and the absorber layer pattern 140P may be disposed on one surface (e.g., the upper surface in the Z direction) of the mask substrate 110. In an embodiment, the reflective layer 120, the capping layer 130, and the absorber layer pattern 140P may be sequentially stacked on one surface of the mask substrate 110 along the Z direction perpendicular to the X and Y directions.

However, the layers positioned on the mask substrate 110 are not necessarily limited thereto and may be changed in various ways in some embodiments. For example, in some embodiments other layers may be additionally disposed between the mask substrate 110, the reflective layer 120, the capping layer 130, and the absorber layer pattern 140P. As another example, a conductive layer may be further positioned on the other side (e.g., a lower side in the Z direction) opposite to one side of the mask substrate 110 where the reflective layer 120, the capping layer 130, and the absorber layer pattern 140P are disposed. For example, the mask substrate 110 may be disposed between the conductive layer and the reflective layer 120 (e.g., in the Z direction).

The reflective layer 120 may be positioned on one surface (e.g., the upper surface in the Z direction) of the mask substrate 110. The reflective layer 120 may reflect light sources of extreme ultraviolet wavelengths. In an embodiment, the reflective layer 120 may have a multi-layered mirror (mirror) structure in which the first reflective layer 120a and the second reflective layer 120b are alternately stacked (e.g., in the Z direction).

The first reflective layer 120a and the second reflective layer 120b may be alternately stacked multiple times (e.g., in the Z direction). In FIG. 3, the stacking structure of the first reflective layer 120a and the second reflective layer 120b is briefly shown for simplicity. However, the number of stacking times of the first reflective layer 120a and the second reflective layer 120b is not necessarily limited to what is shown in FIG. 3. The first reflective layer 120a may be a material layer with a high refractive index, and the second reflective layer 120b may be a material layer with a low refractive index. For example, in an embodiment the reflective layer 120 may have a structure in which the first reflective layer 120a of a high refractive index and the second reflective layer 120b of a low refractive index are formed repeatedly in a range of about 20 to about 60 cycles. However, embodiments of the present disclosure are not necessarily limited thereto. In an embodiment, the uppermost layer (e.g., in the Z direction) of the reflective layer 120 may be the first reflective layer 120a having a high refractive index.

For example, in an embodiment the reflective layer 120 may be composed of a Mo/Si periodic multilayer, a Mo compound/Si compound periodic multilayer, a ruthenium (Ru)/Si periodic multilayer, a beryllium (Be)/Mo periodic multilayer, a Si/niobiumNb) periodic multilayer, a Si/Mo/Ru periodic multilayer, a Si/Mo/Ru/Mo periodic multilayer, or a Si/Ru/Mo/Ru periodic multilayer.

In some embodiments, the reflective layer 120 may be comprised of a molybdenum (Mo)/silicon (Si) periodic multilayer. In this embodiment, the first reflective layer 120a may be formed of silicon with a high refractive index, and the second reflective layer 120b may be formed of molybdenum with a low refractive index.

The material constituting the reflective layer 120 and the thickness of each layer may be appropriately selected depending on the wavelength band of the applied EUV light source or the reflectance of the EUV light source required for the reflective layer 120. For example, in an embodiment in which the reflective layer 120 is made of a Mo/Si periodic multilayer, the Si layer corresponding to the first reflective layer 120a and the Mo layer corresponding to the second reflective layer 120b may each be formed with the thickness within the range of about 2 nm to about 5 nm.

In an embodiment, the reflective layer 120 may be formed using a DC sputtering, a RF sputtering, or an ion beam sputtering process. However, embodiments of the present disclosure are not necessarily limited thereto. For example, when forming the Mo/Si periodic multilayer by using the ion beam sputtering process, Si films and Mo films may be formed alternately as one period that a Si film is deposited using Si as a target and Ar gas as a sputter gas, and a Mo film is deposited using Mo as a target and Ar gas as a sputter gas.

In an embodiment, the capping layer 130 may be disposed on (e.g., dispose directly thereon) the reflective layer 120. The capping layer 130 may protect the reflective layer 120 from damage during the process of repairing the photomask 100. Additionally, the capping layer 130 may prevent the surface of the reflective layer 120 from oxidation.

In some embodiments, the capping layer 130 may be made of ruthenium (Ru) or a ruthenium compound. The ruthenium compound may be a compound including at least one of Ru, Nb, Zr, Mo, Y, B, or La.

In an embodiment, the capping layer 130 may have a thickness in a range of about 1 nm to about 6 nm. In some embodiments, the capping layer 130 may be thicker than the first reflective layer 120a, which is the uppermost layer of the reflective layer 120. For example, the first reflective layer 120a may have a thickness in a range of about 1.5 nm to about 2.5 nm, and the capping layer 130 may have a thickness in a range of about 3 nm to about 6 nm.

The absorber layer pattern 140P may be disposed on (e.g., disposed directly thereon) the capping layer 130. The absorber layer pattern 140P may absorb light sources of extreme ultraviolet wavelengths. The absorber layer pattern 140P may be made of a material that has a low reflectance of light sources of extreme ultraviolet wavelengths while absorbing light sources of extreme ultraviolet wavelengths. The absorber layer pattern 140P may be made of a material that may be removable by an etching process.

According to an embodiment, the absorber layer pattern 140P may include a material with high etch selectivity for the capping layer 130 in the repair process of the photomask 100. For example, in an embodiment the activation energy of the chemical reaction of the material of the absorber layer pattern 140P and the precursor material may be less than the activation energy of the chemical reaction of the material of the capping layer 130 and the precursor material. In other words, when an electron beam is irradiated on the absorber layer pattern 140P and the capping layer 130, the material of the absorber layer pattern 140P may react with the precursor material, but the material of the capping layer 130 may not react with the precursor material. The material of absorber layer pattern 140P may be removed by reacting with the precursor material.

In some embodiments, the absorber layer pattern 140P may have tantalum (Ta) as a main component thereof. In an embodiment, the absorber layer pattern 140P that has tantalum (Ta) as the main component may include at least one element selected among hafnium (Hf), silicon (Si), zirconium (Zr), germanium (Ge), boron (B), nitrogen (N), and hydrogen (H). For example, the absorber layer pattern 140P may be composed of TaN, TaHf, TaHfN, TaBSi, TaBSiN, TaB, TaBN, TaSi, TaSiN, TaGe, TaGEN, TaZr, TaZrN or a combination thereof.

The absorber layer pattern 140P is a patterned absorber layer, and may define an opening OP that allows a light source of extreme ultraviolet wavelength to pass through. The side wall of the absorber layer pattern 140P may be exposed by the opening OP. A light source of extreme ultraviolet wavelength that passes through the opening OP may reach the reflective layer 120 and be reflected.

According to an embodiment, the side wall of the absorber layer pattern 140P exposed by the opening OP may include an inclined surface at an upper portion away from the capping layer 130 (e.g., in the Z direction). The side wall of the absorber layer pattern 140P exposed by the opening OP may include a curved surface at the lower portion adjacent to the capping layer 130. Referring to FIG. 4, the upper portion of the side wall SW of the absorber layer pattern 140P may include an inclined surface SL, and the lower portion of the side wall SW of the absorber layer pattern 140P may include a curved surface CP.

According to an embodiment, the absorber layer pattern 140P may include a light absorber layer 140a and an oxide layer 140b disposed on the light absorber layer 140a. The light absorber layer 140a and the oxide layer 140b may be sequentially stacked on the capping layer 130 along the Z direction. The oxide layer 140b may be the uppermost layer of the absorber layer pattern 140P (e.g., in the Z direction).

In an embodiment, the oxide layer 140b may have a smaller thickness (e.g., length in the Z direction) than the light absorber layer 140a.

In an embodiment, the light absorber layer 140a may be made of, for example, TaN, TaHf, TaHfN, TaBSi, TaBSiN, TaB, TaBN, TaSi, TaSiN, TaGe, TaGEN, TaZr, TaZrN or a combination thereof.

The oxide layer 140b may achieve a sufficient contrast ratio by providing a relatively low reflectance in the wavelength band (e.g., in a range of about 190 nm to about 260 nm) of the light source used in the inspection process of the absorber layer pattern 140P. In an embodiment, the oxide layer 140b may be made of, for example, TaBO, TaBNO, TaOH, TaON, or TaONH.

According to an embodiment, the inclined surface SL may be positioned on the oxide layer 140b. For example, in an embodiment the side wall of oxide layer 140b may include an inclined surface SL. In an embodiment, the side wall of the oxide layer 140b may refer to the part corresponding to the oxide layer 140b among the side wall SW of the absorber layer pattern 140P. In FIG. 4, it is shown that the inclined surface SL is formed on the entire side wall of the oxide layer 140b. However, embodiments of the present disclosure are not necessarily limited thereto, and the inclined surface SL may be formed on only a portion of the side wall of the oxide layer 140b in some embodiments. Thus, the inclined surface SL may be at least a portion of the side wall of the oxide layer 140b.

According to an embodiment, the inclined surface SL may have a decreasing height that gets closer to the capping layer 130 (e.g., in the Z direction) as the distance to a lateral end of the inclined surface SL decreases. The inclined surface SL may have an increasing height that gets farther from the capping layer 130 (e.g., in the Z direction) as the distance from the lateral end of the inclined surface SL increases. The upper surface of the absorber layer pattern 140P may be the upper surface of the oxide layer 140b. Accordingly, a height of the inclined surface SL may increase as the distance from the lateral end of the inclined surface SL increases.

According to an embodiment, the curved surface CP may be defined by a recess RC defined in the side wall of the absorber layer pattern 140P. In an embodiment, the recess RC may be defined on the side wall of the absorber layer pattern 140P and may extend from the inclined surface SL to the upper surface of the capping layer 130. The recess RC may be defined on the side wall of the light absorber layer 140a. Here, the side wall of the light absorber layer 140a may refer to the part corresponding to the light absorber layer 140a among the side wall SW of the absorber layer pattern 140P. In FIG.\ 4, the curved surface CP may be defined as the bottom surface of the recess RC. In an embodiment shown in FIG. 4, the curved surface CP is formed on the entire side wall of the light absorber layer 140a. However, embodiments of the present disclosure are not necessarily limited thereto, and a curved surface CP may be formed on only a portion of the side wall of the light absorber layer 140a in some embodiments.

According to an embodiment, the curved surface CP may be concave in a direction away from the opening OP. As described above, the curved surface CP may be defined as the bottom surface of the recess RC. The depth D of the recess RC may become deeper from the top and bottom surfaces of the side wall towards the middle surface of the side wall of the absorber layer pattern 140P. The side wall of the absorber layer pattern 140P on which the recess RC is formed may be the side wall of the light absorber layer 140a. Accordingly, the depth D of the recess RC may become deeper from the top and bottom surfaces towards the middle surface of the side wall of the light absorber layer 140a.

According to an embodiment, the inclined surface SL and the curved surface CP may overlap in the Z direction. The Z direction may be a direction vertical to one surface side (e.g., an upper surface in the Z direction) of the mask substrate 110. The thickness (e.g., length in the Z direction) of a portion of the absorber layer pattern 140P where the inclined surface SL and the curved surface CP overlap may be thinner than the thickness of other portions of the absorber layer pattern 140P. The thickness of the portion of the absorber layer pattern 140P where the inclined surface SL and the curved surface CP overlap may need to be thicker for the absorber layer pattern 140P to absorb a light source of extreme ultraviolet wavelength. Accordingly, the light source of extreme ultraviolet wavelength may reach the capping layer 130 and the reflective layer 120 by passing through the portion of the absorber layer pattern 140P that overlaps the inclined surface SL and the curved surface CP in the Z direction. Accordingly, the portion of the reflective layer 120 that overlaps the inclined surface SL and the curved surface CP in the Z direction may reflect a light source of extreme ultraviolet wavelength. Due to the compensation of reflectivity, a critical dimension (CD) in the defect region DF may be corrected. For example, the critical dimension (CD) in the defect region DF may be corrected by the overlap width of the inclined surface SL and the curved surface CP.

According to an embodiment, the overlap width of the inclined surface SL and the curved surface CP may be less than about 15 nm. According to an embodiment, a defect region (DF in FIG. 1) with a width of less than about 15 nm may be repaired.

According to an embodiment, the depth D of the recess RC may be less than the width W of the inclined surface SL.

The depth D of the recess RC and the width W of the inclined surface SL may mean the length in the X direction. The X direction may be a direction parallel to one surface (e.g., an upper surface in the Z direction) of the mask substrate 110, and may be in a direction that the defect region (DF in FIG. 1) protrudes from the side wall of the absorber layer pattern 140P.

As the depth D of the recess RC is less than the width W of the inclined surface SL, the overlap width of the inclined surface SL and the curved surface CP may correspond to the depth D of the recess RC. According to the above, the overlap width between the inclined surface SL and the curved surface CP may be less than about 15 nm. According to an embodiment, the depth D of the recess RC may be less than about 15 nm.

Referring to FIG. 5, the absorber layer pattern 140P may include a first side wall SW1 and a second side wall SW2 facing each other with the opening OP in between. For example, the defect region DF may exist on both of the first side wall SW1 and the second side wall SW2. In this embodiment, the first side wall SW1 and the second side wall SW2 may be simultaneously repaired with a single electron beam irradiation. However, embodiments of the present disclosure are not necessarily limited thereto, and both sidewalls may be repaired separately by irradiating an electron beam to each of the first side wall SW1 and the second side wall SW2.

Referring to FIG. 4. according to the above, the absorber layer pattern 140P may include a light absorber layer 140a and an oxide layer 140b disposed above the light absorber layer 140a and having a thickness (e.g., length in the Z direction) that is less than a thickness (e.g., length in the Z direction) of the light absorber layer 140a. The oxide layer 140b may be the uppermost layer of the absorber layer pattern 140P. For the light absorber layer 140a and the oxide layer 140b, since the content above-mentioned with reference to FIG. 4 may be applied equally, duplicate content is simplified or omitted.

The first side wall SW1 may include a first inclined surface SL1 on the upper portion away from the capping layer 130 (e.g., in the Z direction), and a first curved surface CP1 on the lower portion adjacent to the capping layer 130 (e.g., in the Z direction). The second side wall SW2 may include a second inclined surface SL2 on the upper portion away from the capping layer 130 (e.g., in the Z direction), and a second curved surface CP2 on the lower portion adjacent to the capping layer 130 (e.g., in the Z direction). The first inclined surface SL1 and the second inclined surface SL2 may be positioned on the side wall of oxide layer 140b. The first curved surface CP1 and the second curved surface CP2 may be positioned on the side wall of the light absorber layer 140a.

In an embodiment, the first side wall SW1 may include a first recess RC1 in a portion corresponding to the light absorber layer 140a, and the second side wall SW2 may include a second recess RC2 in a portion corresponding to the light absorber layer 140a. The first curved surface CP1 may be defined by the first recess RC1, and the second curved surface CP2 may be defined by the second recess RC2. The first curved surface CP1 may be defined as the bottom surface of the first recess RC1, and the second curved surface CP2 may be defined as the bottom surface of the second recess RC2.

For the first inclined surface SL1, the first curved surface CP1, and the first recess RC1, the above-described description for the inclined surface SL, the curved surface CP, and the recess RC with reference to FIG. 4 may be equally applied. Regarding the second inclined surface SL2, the second curved surface CP2, and the second recess RC2, the contents of the inclined surface SL, the curved surface CP, and the recess RC described above with reference to FIG. 4. may be applied equally.

According to an embodiment, the shape of the first side wall SW1 and the shape of the second side wall SW2 may be symmetrical. For example, the shape of the first inclined surface SL1 and the shape of the second inclined surface SL2 may be symmetrical to each other (e.g., mirror symmetry). The shape of the first curved surface CP1 and the shape of the second curved surface CP2 may be symmetrical (e.g., mirror symmetry). The shape of the first recess RC1 and the shape of the second recess RC2 may be symmetrical (e.g., mirror symmetry).

The first inclined surface SL1 and the second inclined surface SL2 may have a decreasing height that gets closer to the capping layer 130 (e.g., in the Z direction) as distances to lateral ends of the first and second incline surfaces SL1, SL2 decrease, respectively. The first inclined surface SL1 and the second inclined surface SL2 may have an increasing height that get farther from the capping layer 130 (e.g., in the Z direction) as distances to lateral ends of the first and second inclined surfaces SL1, SL2 increase, respectively. The first inclined surface SL1 and the second inclined surface SL2 may decrease from the uppermost surface to the bottommost surface of the oxide layer 140b.

The first curved surface CP1 and the second curved surface CP2 may be concave in a direction away from the opening OP. The depth of the first recess RC1 and the second recess RC2 may become deeper from the top and bottom surfaces towards the middle surface of the side wall of the light absorber layer 140a.

The first inclined surface SL1 and the first curved surface CP1 may overlap in the Z direction. The second inclined surface SL2 and the second curved surface CP2 may overlap in the Z direction. The Z direction may be a direction vertical to one surface (e.g., an upper surface in the z direction) of the mask substrate 110. The portion of the reflective layer 120 that overlaps the first inclined surface SL and the first curved surface CP1 in the Z direction may reflect a light source of extreme ultraviolet wavelength. The portion of the reflective layer 120 that overlaps the second inclined surface SL2 and the second curved surface CP2 in the Z direction may reflect a light source of extreme ultraviolet wavelength. For example, the reflectivity may be compensated by the overlap width of the first inclined surface SL1 and the first curved surface CP1, and by the overlap width of the second inclined surface SL2 and the second curved surface CP2.

In an embodiment, the overlap width of the first inclined surface SL1 and the first curved surface CP1 may be less than about 15 nm. The overlap width of the second inclined surface SL2 and the second curved surface CP2 may be less than about 15 nm. According to an embodiment, the defect region (DF in FIG. 1) with the width of less than about 15 nm formed on the first side wall SW1 and the second side wall SW2 may be repaired.

According to an embodiment, the maximum width of the opening OP defined by the inclined surfaces SL1 and SL2 may be greater than the maximum width of the opening OP defined by the curved surfaces CP1 and CP2. For example, the maximum width (e.g., length in the X direction) of the opening OP defined by the first inclined surface SL1 and the second inclined surface SL2 may be greater than the maximum width (e.g., length in the X direction) of the opening OP defined by the first curved surface CP1 and the second curved surface CP2. This may be applied even when the defect region (DF in FIG. 1) exists on only one of the first side wall SW1 and the second side wall SW2, and then the inclined surface SL and curved surface CP are formed only on one of the first side wall SW1 and the second side wall SW2.

Referring to FIG. 2 to FIG. 5, according to the above-described embodiments, the side wall of the absorber layer pattern 140P exposed by the opening OP may include an inclined surface SL that has a decreasing height that gets closer to the capping layer 130 as a distance to a lateral end of the inclined surfaces SL decreases, and a curved surface CP that is concave in a direction away from the opening OP. Since the CD of the absorber layer pattern 140P is finely corrected by the overlap width of the inclined surface SL and the curved surface CP, defects less than about 15 nm may be repaired.

Hereinafter, a repair method of the photomask for the extreme ultraviolet lithography according to some embodiments is described with reference to FIG. 6 to FIG. 14.

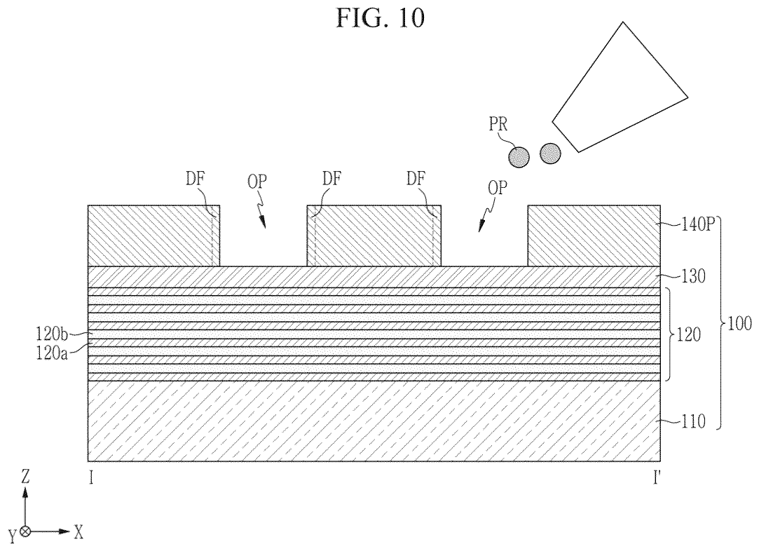

FIG. 6 to FIG. 14 are cross-sectional views to explain a repair method of a photomask for an extreme ultraviolet lithography according to some embodiments, and may correspond to the cross-section taken along the line I-I′ of FIG. 2. In detail, FIG. 6 to FIG. 9 may corresponding to a process of patterning of an absorber layer 140 of a photomask for an extreme ultraviolet lithography 100, and FIG. 10 to FIG. 14 may corresponding to a process of repairing a defect region DF of the absorber layer pattern 140P of the photomask for extreme ultraviolet lithography 100.

Referring to FIG. 6, the photomask 100 including a mask substrate 110, a reflective layer 120 disposed on (e.g., disposed directly thereon) one surface (e.g., an upper surface in the Z direction) of the mask substrate 110, a capping layer 130 disposed on (e.g., disposed directly thereon) the reflective layer 120, and the absorber layer 140 disposed on (e.g., disposed directly thereon) the capping layer 130 may be provided.

The reflective layer 120 may reflect a light source in the extreme ultraviolet wavelength band. In an embodiment, the reflective layer 120 may be formed by alternately stacking (e.g., in the Z direction) a first reflective layer 120a with a high refractive index and a second reflective layer 120b with a low refractive index. In an embodiment, the first reflective layer 120a may include, for example, silicon. However, embodiments of the present disclosure are not necessarily limited thereto. In an embodiment, the second reflective layer 120b may include, for example, molybdenum. However, embodiments of the present disclosure are not necessarily limited thereto.

The capping layer 130 protects the reflective layer 120 from damage in the subsequent repair process and may prevent the oxidation of the surface of reflective layer 120. In an embodiment, the capping layer 130 may be made of, for example, ruthenium (Ru) or a ruthenium compound. The ruthenium compound may be a compound including at least one of Ru, Nb, Zr, Mo, Y, B, or La.

The absorber layer 140 may absorb light sources of extreme ultraviolet wavelengths. The absorber layer 140 may be made of a material that absorbs light sources of extreme ultraviolet wavelengths and has a low reflectivity of light sources of extreme ultraviolet wavelengths. The absorber layer 140 may include a material with high etch selectivity to the capping layer 130 in the subsequent repair process. In an embodiment, the absorber layer 140 may be made of, for example, a tantalum (Ta)-based material. The absorber layer 140, for example, may be formed of TaN, TaHf, TaHfN, TaBSi, TaBSiN, TaB, TaBN, TaSi, TaSiN, TaGe, TaGeN, TaZr, TaZrN, or a combination thereof.

A photoresist layer 150 may be formed on (e.g., formed directly thereon in the Z direction) the absorber layer 140.

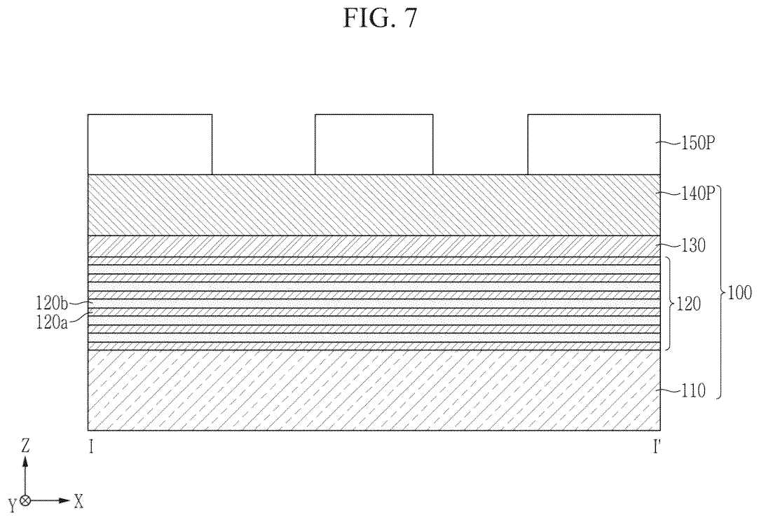

Referring to FIG. 7, a photoresist pattern 150P may be formed on (e.g., formed directly thereon in the Z direction) the absorber layer 140. In an embodiment, a photoresist pattern 150P may be formed through an exposing and developing process of the photoresist layer 150 in FIG. 6.

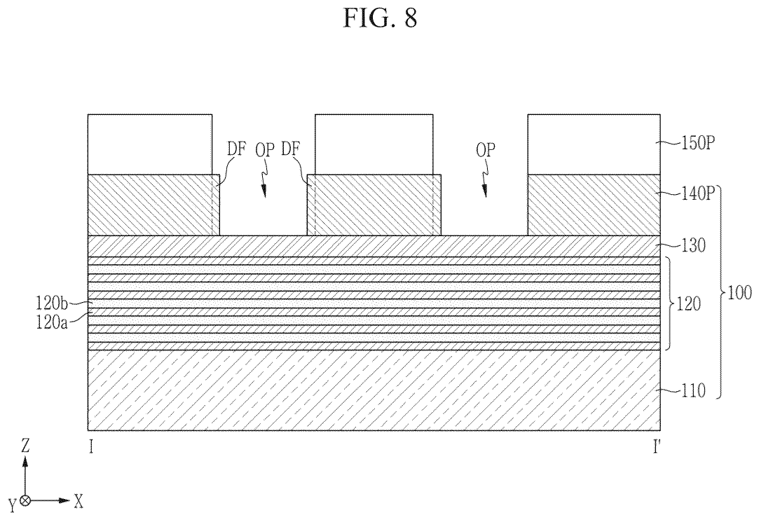

Referring to FIG. 8, an absorber layer pattern 140P may be formed on (e.g., formed directly thereon in the Z direction) the capping layer 130. In an embodiment, the absorber layer 140 may be etched by using the photoresist pattern 150P of FIG. 7 as an etching mask to form the absorber layer pattern 140P. The absorber layer pattern 140P may define one or more openings OP penetrating at least absorber layer 140 in the direction vertical to the mask substrate 110 (e.g., the Z direction). In the extreme ultraviolet lithography process, a light source of extreme ultraviolet wavelength that passes through the opening OP may pass through the capping layer 130, reach the reflective layer 120, and be reflected.

The absorber layer pattern 140P shown in FIG. 8 may include at least one defect region DF. In an embodiment, the defect region DF may be a region subject to the etching in an etching process using a photoresist pattern 150P, or a region remaining without an etching. The defect region DF may protrude from the side wall of the absorber layer pattern 140P in a direction parallel to the mask substrate 110. For example, in an embodiment, the defect region DF may protrude in the X direction.

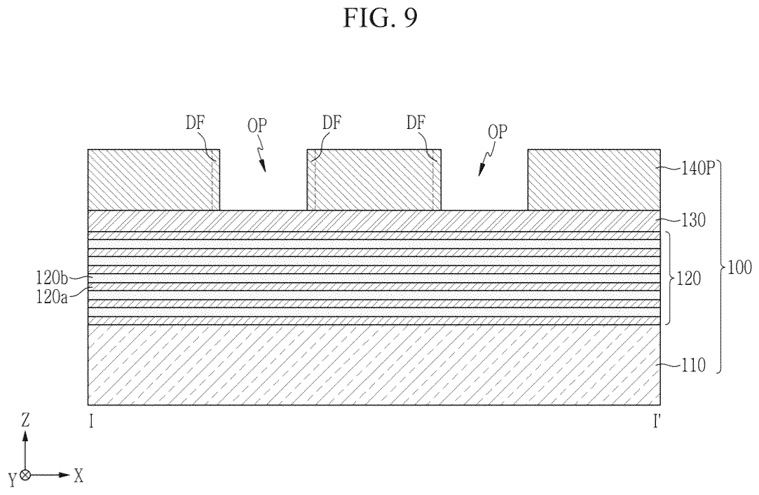

Referring to FIG. 9, the photoresist pattern 150P may be removed. For example, in an embodiment, the photoresist pattern 150P may be removed by an ashing process. The photomask 100 shown in FIG. 9 corresponds to the photomask 100 shown in FIG. 1. The photomask 100 shown in FIG. 9 may be in a state before performing the repair process.

Referring to FIG. 10, a precursor PR may be supplied to the photomask 100. In an embodiment, the precursor PR may be, for example, a fluorine (F)-based gas. The precursor PR may be etched by reacting with the material of the absorber layer pattern 140P. An activation energy is required for the materials of the precursor PR and the absorber layer pattern 140P to be reacted, and the reaction of the material of the absorber layer pattern 140P and the precursor PR may be activated by irradiating an electron beam to the absorber layer pattern 140P.

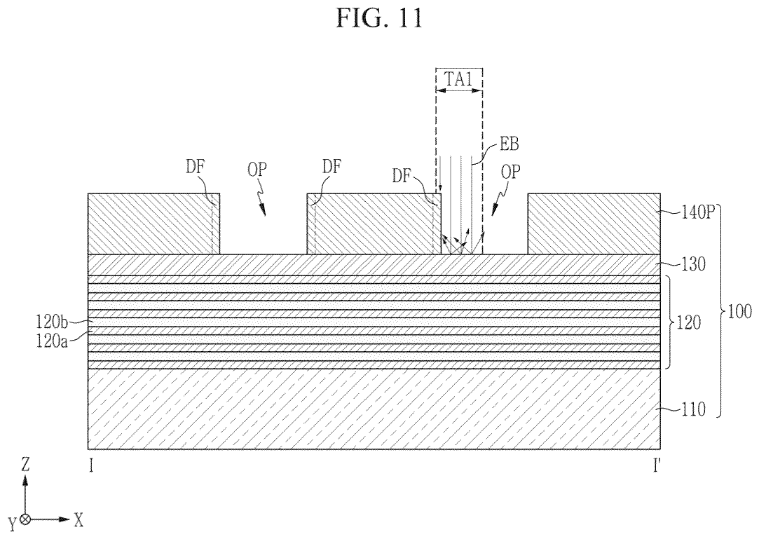

Referring to FIG. 11, an electron beam EB may be irradiated to the portion of the absorber layer pattern 140P including at least a portion of the defect region DF and a portion of the capping layer 130 adjacent thereto. According to an embodiment, an electron beam EB may be irradiated while the precursor PR is supplied to the photomask 100. However, embodiments of the present disclosure are not necessarily limited thereto. For example, the precursor PR may be supplied simultaneously when the electron beam EB is irradiated, or may be supplied after the electron beam EB is irradiated.

In an embodiment, the activation energy required for the reaction of the material of the precursor PR and the absorber layer pattern 140P may be less than the activation energy required for the reaction of the material of the precursor PR and the capping layer 130. For example, when the electron beam EB is irradiated to the absorber layer pattern 140P and the capping layer 130 with the same irradiation dose, the amount of the reaction of the material of the precursor PR and the absorber layer pattern 140P may be much greater than the amount of the reaction of the material of precursor PR and the capping layer 130. For example, compared to the absorber layer pattern 140P being etched, the capping layer 130 may not be etched at all.

According to an embodiment, the electron beam EB irradiated to a portion of the absorber layer pattern 140P may collide with the upper surface of the absorber layer pattern 140P. Accordingly, the etching in the vertical direction may occur in the uppermost layer of the absorber layer pattern 140P. In an embodiment, the uppermost layer of the absorber layer pattern 140P may be an oxide layer. The uppermost layer of the absorber layer pattern 140P may be made of a material different from the material of the absorber layer 140 described above. In an embodiment, the uppermost layer of the absorber layer pattern 140P, for example, may be formed of TaBO, TaBNO, TaOH, TaON, or TaONH.

According to an embodiment, the electron beam EB irradiated to a portion of the capping layer 130 collides with the upper surface of the capping layer 130 and is scattered, and the scattered electrons may collide with the side wall of the absorber layer pattern 140P. Accordingly, the etching in the side direction of the absorber layer pattern 140P may occur. By the electrons scattered by colliding with the capping layer 130, the side wall of the absorber layer pattern 140P positioned between the uppermost layer of the absorber layer pattern 140P and the capping layer 130 may be etched. The side wall of the absorber layer pattern 140P positioned between the uppermost layer of the absorber layer pattern 140P and the capping layer 130 may be made of the same material as the material of the absorber layer 140 described above.

In the case of the side wall of the absorber layer pattern 140P, since it is not covered by an oxide layer, a spontaneous reaction between the material of the absorber layer 140 and the precursor PR may occur relatively easily. Accordingly, if the irradiation dose of the electron beam EB exceeds a certain range, an over-etching may occur due to the acceleration of the spontaneous reaction. Accordingly, the electron beam EB may be irradiated with a dose that may control the over-etching on the side wall of the absorber layer pattern 140P while etching the absorber layer pattern 140P to some extent to enable the CD correction in the defect region DF.

According to an embodiment, the radiation dose of the electron beam EB may be in a range of between about 35% and about 45% of the radiation dose that completely removes the portion of the absorber layer pattern 140P corresponding to the defect region DF. For example, in an embodiment the radiation dose of the electron beam EB may be about 40% of the radiation dose that removes an entirety of the portion of the absorber layer pattern 140P corresponding to the defect region DF. When the electron beam EB is irradiated with about 40% of the irradiation dose that completely removes the portion of the absorber layer pattern 140P corresponding to the defect region DF, the material of the absorber layer pattern 140P that collides with the electrons of the electron beam EB may be partially removed by reacting with the precursor PR. The electron beam EB irradiated on the absorber layer pattern 140P may etch the uppermost layer of the absorber layer pattern 140P. The electron beam EB irradiated and scattered on the capping layer 130 may etch the side wall of the absorber layer pattern 140P.

In FIG. 11, the electron beam EB may be irradiated by targeting the first region TA1. The first region TA1 may include a portion of the absorber layer pattern 140P and a portion of the capping layer 130 adjacent thereto. When the electron beam EB is irradiated to the target material, an interaction volume that affects even unirradiated areas may occur. Accordingly, the electron beam EB may target and irradiate a region narrower than the defect region DF. For example, the width (e.g., length in the X direction) of the portion of the absorber layer pattern 140P included in the first region TA1 may be less than the width (e.g., length in the X direction) of the defect region DF. The first region TA1 may include a portion of the absorber layer pattern 140P corresponding to at least a portion of the defect region DF and a portion of the capping layer 130 adjacent thereto.

In contrast to a comparative example in which the irradiation dose of the electron beam EB is set to 100% to remove all parts of the absorber layer pattern 140P corresponding to the defect region DF, and the electron beam EB is irradiated only to some regions of the absorber layer pattern 140P, in an embodiment of the present disclosure the region where the electron beam EB is irradiated may be overtargeted and the irradiation dose of the electron beam EB may be reduced. The region where the electron beam EB is irradiated to the absorber layer pattern 140P according to an embodiment of the present disclosure may be wider than the region where the electron beam EB is irradiated to the absorber layer pattern 140P according to the comparative example. Additionally, according to an embodiment of the present disclosure, the electron beam EB may also be irradiated to a portion of the capping layer 130 adjacent to the portion of the absorber layer pattern 140P to which the electron beam EB is irradiated. The region where the electron beam EB according to an embodiment of the present disclosure is irradiated is wider than the region where the electron beam EB of the comparative example is irradiated, but the irradiation dose of the electron beam EB according to an embodiment of the present disclosure may be in a range of about 35% to about 45% times that of the electron beam EB of the comparative example. Accordingly, in an embodiment of the present disclosure, an inclined surface may be formed on the uppermost layer of the portion of absorber layer pattern 140P where the electron beam EB was irradiated.

For example, the first region TA1 may be the target region of the electron beam EB in a case in which the defect region DF is formed on only one side of both sidewalls of the absorber layer pattern 140P facing each other with the opening OP in between. The amount that the electrons scattered by colliding with the portion of the capping layer 130 included in the first region TA1 collides with the side wall of the absorber layer pattern 140P adjacent to the part of the capping layer 130 may be greater than the amount of the collision on the other side wall of the absorber layer pattern 140P facing the side wall of the absorber layer pattern 140P. For example, when irradiating the electron beam EB by targeting the first region TA1, the defect region DF formed in the absorber layer pattern 140P positioned on the one side of the opening OP may be repaired.

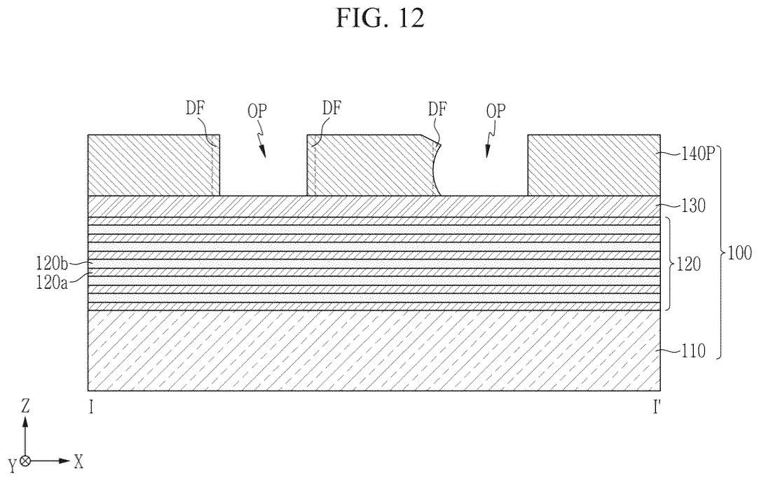

Referring to FIG. 12, an inclined surface that has a decreasing height that gets closer the capping layer 130 as a distance to a lateral end of the inclined surface decreases may be formed at the upper portion of the absorber layer pattern 140P, and a curved surface concave in a direction away from the opening OP may be formed under the inclined surface. The inclined surface may be formed on (e.g., formed directly thereon) the oxide layer which is the uppermost layer of the absorber layer pattern 140P. In an embodiment, the inclined surface may be formed wider than the width (e.g., length in the X direction) of the defect region DF. The curved surface may be defined as the bottom surface of the recess formed on the side wall of the absorber layer pattern 140P. In an embodiment, the depth of the recess may be formed to be narrower than the width of the inclined surface (e.g., length in the X direction). The depth of the recess may be greater than or equal to the width of the defect region DF (e.g., length in the X direction).

The inclined surface and the curved surface may overlap in the vertical direction (e.g., the Z direction) to one side of the mask substrate 110. The absorber layer pattern 140P may need to have a sufficient thickness to absorb light sources of extreme ultraviolet wavelengths. For example, to absorb a light source of extreme ultraviolet wavelength, the absorber layer pattern 140P may need to be thicker than a thickness of the portion of the absorber layer pattern 140P where the inclined surface and the curved surface overlap. The portion of the absorber layer pattern 140P where the inclined surface and the curved surface overlap may not completely absorb light sources of extreme ultraviolet wavelengths. The light source of extreme ultraviolet wavelength that passes through the portion of the absorber layer pattern 140P where the inclined surface and the curved surface overlap may reach the capping layer 130 and the reflective layer 120 and be reflected. For example, the reflectivity of the photomask 100 may be compensated by the width of the portion of the absorber layer pattern 140P where the inclined surface and the curved surface overlap. The CD in the defect region DF may be corrected by the width of the portion of the absorber layer pattern 140P where the inclined surface and the curved surface overlap.

According to an embodiment of the present disclosure, the overlapping width (e.g., length in the X direction) of the inclined surface and the curved surface in the Z direction may be less than about 15 nm. Accordingly, the CD correction of less than about 15 nm in the defect region DF is possible.

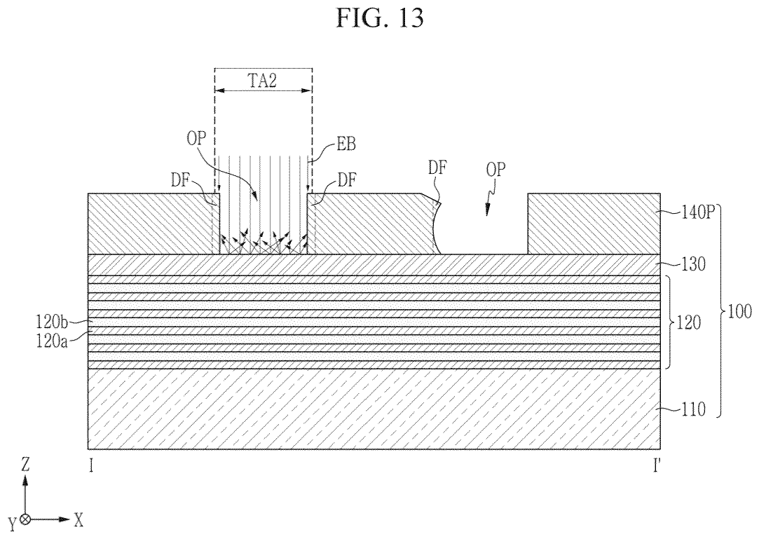

Referring to FIG. 13, an electron beam EB may be irradiated by targeting a second region TA2. According to an embodiment, the photomask 100 in FIG. 13 may be in a state in which the precursor PR is supplied. According to an embodiment, the electron beam EB may be irradiated while the precursor PR is supplied to the photomask 100. However, embodiments of the present disclosure are not necessarily limited thereto. For example, the precursor PR may be supplied simultaneously when the electron beam EB is irradiated, or may be supplied after the electron beam EB is irradiated.

According to an embodiment, the width (e.g., length in the X direction) of the second region TA2 may be larger than the width (e.g., length in the X direction) of the first region TA1 of FIG. 11. The second region TA2 may include portions of the absorber layer pattern 140P positioned on both sides with the opening OP in between and a portion of the capping layer 130 adjacent thereto. The second region TA2 may be a target region of the electron beam EB when the defect region DF is formed on both sidewalls of the absorber layer pattern 140P with the opening OP in between.

According to an embodiment, the electron beam EB irradiated to the portion of the absorber layer pattern 140P may collide with the upper surface of the absorber layer pattern 140P. Accordingly, the etching in the vertical direction may occur in the uppermost layer of the absorber layer pattern 140P. The electron beam EB irradiated to the portion of the capping layer 130 collides with the upper surface of the capping layer 130 and is scattered, and the scattered electrons may collide with the side wall of the absorber layer pattern 140P. Accordingly, the etching in the side direction of the absorber layer pattern 140P may occur. Due to the electrons scattered by the colliding with the capping layer 130, the side wall of the absorber layer pattern 140P positioned between the uppermost layer of the absorber layer pattern 140P and the capping layer 130 may be etched.

The electrons scattered by the colliding with the portion of the capping layer 130 included in the second region TA2 may collide with both sidewalls of the opposing absorber layer pattern 140P. For example, when irradiating the electron beam EB by targeting the second region TA2, the defect regions DF formed on both sidewalls of the absorber layer pattern 140P facing each other with the opening OP in between may be simultaneously repaired.

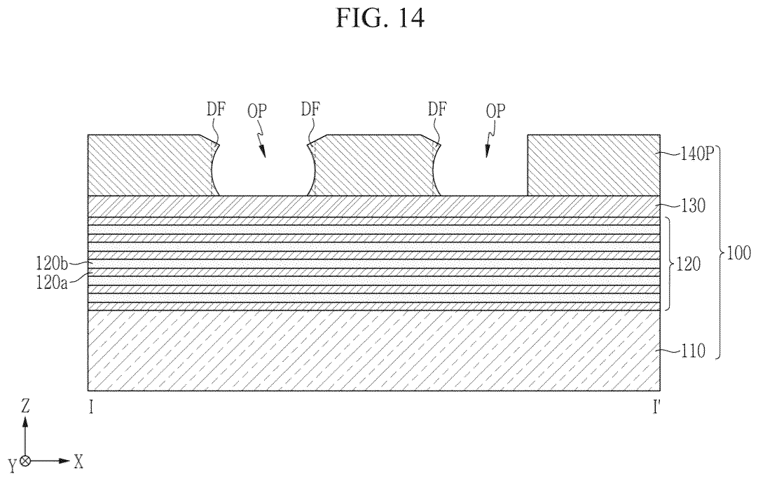

Referring to FIG. 14, at the upper portion of both sidewalls of the absorber layer pattern 140P facing each other via the opening OP, an inclined surface having a decreasing height that gets closer to the capping layer 130 as a distance to a lateral end of the inclined surface decreases is formed, and a curved surface concave in a direction away from the opening OP may be formed under the inclined surface. The inclined surface and the curved surface formed on both sidewalls of the absorber layer pattern 140P facing each other with the opening OP in between may have a shape that is symmetrical to each other. For the inclined surface and the curved surface formed on each side wall of the absorber layer pattern 140P, since the above-described content referring to FIG. 12 may be applied equally, redundant explanations will be simplified or omitted.

Each inclined surface may be formed wider (e.g., a length in the X direction) than the width (e.g., a length in the X direction) of the defect region DF formed on the side wall of the absorber layer pattern 140P, which is the same as the inclined surface. The curved surface may be defined as the bottom surface of the recess formed on the side wall of the absorber layer pattern 140P. The depth of the recess may be less than the width (e.g., length in the X direction) of the inclined surface formed on the side wall of the absorber layer pattern 140P, which is the same as the recess. The depth of the recess may be greater than or equal to the width (e.g., length in the X direction) of the defect region DF formed on the side wall of the absorber layer pattern 140P, which is the same as the recess.

The inclined surface and the curved surface formed on each side wall of the absorber layer pattern 140P may overlap in the direction (e.g., the Z direction) that is vertical to one surface (e.g., an upper surface in the Z direction) of the mask substrate 110. According to an embodiment, the CD in the defect region DF may be corrected by the width of the portion of the absorber layer pattern 140P where the inclined surface and the curved surface overlap. According to an embodiment, the overlap width (the width in the X direction) in the Z direction of the inclined surface and the curved surface formed on each side wall of the absorber layer pattern 140P may be less than about 15 nm. Accordingly, the CD correction of less than about 15 nm is possible in each defect region DF formed on both sidewalls of the absorber layer pattern 140P.

The photomask 100 shown in FIG. 14 may correspond to the photomask 100 shown in FIG. 2 and FIG. 3. The photomask 100 shown in FIG. 14 may be a state that the repair process is completed.

Referring to FIG. 6 to FIG. 14, according to the above-described embodiment, the irradiation dose of the electron beam EB is set to about 40% of the irradiation dose that removes all of the portion of the absorber layer pattern 140P corresponding to the defect region DF, the electron beam EB is irradiated by targeting the region that includes the portion of the absorber layer pattern 140P including at least a portion of the defect region DF and the portion of the capping layer 130 adjacent thereto, thereby repairing the defect region DF

Through this repair process, an inclined surface having a decreasing height that gets closer to the capping layer 130 as a distance to a lateral end of the inclined surface decreases may be formed on the upper portion of the absorber layer pattern 140P, and a curved surface concave in a direction away from the opening OP may be formed below the inclined surface. The CD of the absorber layer pattern 140P may be finely corrected by the overlap width of the inclined surface and the curved surface in the direction perpendicular to the mask substrate 110, and the overlap width of the inclined surface and the curved surface may be less than about 15 nm. Accordingly, the defect region DF of less than about 15 nm of the absorber layer pattern 140P may be repaired.

While this disclosure has been described in connection with non-limiting embodiments, it is to be understood that the present disclosure is not limited to the described embodiments. On the contrary, the present disclosure is intended to cover various modifications and equivalent arrangements.

What is claimed is:

1. A photomask comprising:
a mask substrate,
a reflective layer disposed on a first surface of the mask substrate;
a capping layer disposed on the reflective layer, and
an absorber layer pattern that is disposed on the capping layer, the absorber layer pattern defines an opening that light sources of extreme ultraviolet wavelengths pass through,
wherein a side wall of the absorber layer pattern exposed by the opening includes an inclined surface on an upper portion disposed away from the capping layer and a curved surface on a lower portion adjacent to the capping layer.

2. The photomask of claim 1, wherein:
the inclined surface has a height that decreases and gets closer to the capping layer as a distance to a lateral end of the inclined surface decreases.

3. The photomask of claim 1, wherein:
the absorber layer pattern includes a light absorber layer and an oxide layer disposed on the light absorber layer, the oxide layer having a thickness that is less than a thickness of the light absorber layer; and
the inclined surface is at least a portion of a side wall of the oxide layer.

4. The photomask of claim 1, wherein:
the curved surface is concave in a direction away from the opening.

5. The photomask of claim 1, wherein:
a maximum width of the opening defined by the inclined surface is greater than a maximum width of the opening defined by the curved surface.

6. The photomask of claim 1, wherein:
the inclined surface and the curved surface overlap in a direction vertical to the first surface of the mask substrate, wherein an overlap width of the inclined surface and the curved surface is less than about 15 nm.

7. The photomask of claim 1, wherein:
the absorber layer pattern includes a first side wall and a second side wall facing each other with the opening in between; and
a shape of the first side wall and a shape of the second side wall are symmetrical to each other.

8. The photomask of claim 1, wherein:
a portion of the reflective layer that overlaps the inclined surface and the curved surface in a direction vertical to the first surface of the mask substrate reflects light from the light sources.

9. The photomask of claim 1, wherein:
the absorber layer pattern includes a material having high etch selectivity relative to the capping layer.

10. A photomask comprising:
a mask substrate,
a reflective layer disposed on a first surface of the mask substrate,
a capping layer disposed on the reflective layer, and
an absorber layer pattern that is disposed on the capping layer, the absorber layer pattern defines an opening that light sources of extreme ultraviolet wavelengths pass through,
wherein a side wall of an uppermost layer of the absorber layer pattern includes an inclined surface, and
a side wall of the absorber layer pattern extending from the inclined surface to an upper surface of the capping layer includes a curved surface.

11. The photomask of claim 10, wherein:
the inclined surface has a height that increases and gets farther from the capping layer as a distance to a lateral end of the inclined surface increases.

12. The photomask of claim 10, wherein:
the uppermost layer of the absorber layer pattern is an oxide layer.

13. The photomask of claim 10, wherein:
the curved surface is defined by a recess defined in the side wall of the absorber layer pattern; and
a depth of the recess becomes increases from a top surface and a bottom surface to a middle surface of the side wall of the absorber layer pattern.

14. The photomask of claim 13, wherein:
the depth of the recess is less than a width of the inclined surface.

15. The photomask of claim 14, wherein:
the depth of the recess is less than about 15 nm.

16. A repair method of a photomask comprising:
providing a photomask including a mask substrate, a reflective layer disposed on a first surface of the mask substrate, a capping layer disposed on the reflective layer, and an absorber layer pattern disposed on the capping layer, the absorber layer pattern defining an opening that light sources of extreme ultraviolet wavelengths pass through;
supplying a precursor to the photomask; and
irradiating an electron beam to a portion of the absorber layer pattern that includes at least a portion of a defective region of the photomask and to a portion of the capping layer adjacent to the portion of the absorber layer pattern.

17. The repair method of the photomask of claim 16, wherein:
a radiation dose of the electron beam that irradiates the portion of the absorber layer pattern and the portion of the capping layer is in a range of about 35% to about 45% of a first radiation dose that completely removes the portion of the absorber layer pattern.

18. The repair method of the photomask of claim 16, wherein:
the electron beam irradiated to the portion of the absorber layer pattern collides with an upper surface of the absorber layer pattern; and
the electron beam irradiated to the portion of the capping layer is scattered by colliding with an upper surface of the capping layer, and scattered electrons of the electron beam collide with a side wall of the absorber layer pattern.

19. The repair method of the photomask of claim 18, wherein:
a material of the absorber layer pattern that collides with electrons of the electron beam reacts with the precursor and is partially removed;
an inclined surface that has a height that decreases and gets closer to the capping layer as a distance to a lateral end of the inclined surface decreases is formed at an upper portion of the absorber layer pattern, and
a curved surface concave in a direction away from the opening is formed below the inclined surface.

20. The photomask of claim 19, wherein:
an overlap width of the inclined surface and the curved surface in a direction vertical to the first surface of the mask substrate is less than about 15 nm.
